(19) United States
(12) Patent Application Publication
(10) Pub. No.: US 2015/0003065 A1
(43) Pub. Date: Jan. 1, 2015

(54) LED LIGHTING ASSEMBLY AND AN ILLUMINATING APPARATUS HAVING THE LED LIGHTING ASSEMBLY

(71) Applicants: Peng Chen, Shenzhen (CN); Xiaomian Chen, Shenzhen (CN); ChengCheng Feng, Shenzhen (CN); Hao Li, Shenzhen (CN)

(72) Inventors: Peng Chen, Shenzhen (CN); Xiaomian Chen, Shenzhen (CN); ChengCheng Feng, Shenzhen (CN); Hao Li, Shenzhen (CN)

(73) Assignee: OSRAM GmbH, Muenchen (DE)

(21) Appl. No.: 14/241,102

(22) PCT Filed: Aug. 31, 2012
(86) PCT No.: PCT/EP2012/066992

§ 371 Date: May 5, 2014

(30) Foreign Application Priority Data
Sep. 5, 2011 (CN) 201110261158.0

(51) Int. Cl. H01L 33/64; H01L 25/13; F21V 29/00; H01L 33/62

(52) U.S. Cl. CPC H01L 33/642; H01L 33/641; H01L 33/62; H01L 25/13; F21V 29/002
USPC 362/249.02; 257/99

(57) ABSTRACT

An LED lighting assembly may include: a substrate, a metal layer applied on the substrate, and an LED chip provided on the metal layer, wherein the metal layer comprises a first region for heat dissipation and two second regions for electric conduction, and the first region and the two second regions are electrically insulated from each other, and wherein the LED chip is provided in the first region and is respectively electrically connected with the two second regions via wires.

### RELATED APPLICATIONS

The present application is a national stage entry according to 35 U.S.C. §371 of PCT application No.: PCT/EP2012/066992 filed on Aug. 31, 2012, which claims priority from Chinese application No.: 201110261158.0 filed on Sep. 5, 2011, and is incorporated herein by reference in its entirety.

### TECHNICAL FIELD

Various embodiments relate to an LED lighting assembly. In addition, various embodiments further relate to an illuminating apparatus having the LED lighting assembly of the above type.

### BACKGROUND

With the development of the LED technology, the LED lighting assembly becomes more and more popular. People usually would like to use a COB chip-on-board package technology to manufacture the LED lighting assembly because such COB chip-on-board package LED has the advantages such as a compact size, a low cost and a small thermal resistance. Similar to the traditional LED lighting assemblies, the thermal dissipating performance of the COB package LED lighting assembly is also a key factor that affects the luminescent efficiency and service life of the LED lighting assembly. In the known prior art, the COB chip-on-board package LED lighting assembly can be classified into three categories: FR4-based COB chip-on-board package LED lighting assembly, MCPCB-based COB chip-on-board package LED lighting assembly and ceramic based COB chip-on-board package LED lighting assembly.

In a traditional FR4-based COB chip-on-board package LED lighting assembly, an FR4 substrate is applied with a metal layer on which an LED chip is provided and electrically connected with the metal layer via a wire (generally a gold wire). The metal layer herein acts as both an electric conduction path of a power supplied to the LED chip and a thermal dissipating path of the LED chip. However, the heat from the metal layer cannot be quickly dissipated to the outside since the FR4 substrate has a poor thermal dissipating performance. Therefore, though the cost of the FR4-based COB chip-on-board package is relatively low, the thermal dissipating performance thereof is relatively poor compared with the other two COB chip-on-board packages. But the MCPCB-based COB chip-on-board package and ceramic based COB chip-on-board package are more expensive than the FR4-based COB chip-on-board package though they have a very good thermal dissipating performance.

### SUMMARY

Various embodiments provide an LED lighting assembly having a very good thermal dissipating performance and a relatively low cost. In addition, various embodiments also provide an illuminating apparatus having the LED lighting assembly of the above type.

According to various embodiments, the LED lighting assembly include a substrate, a metal layer applied on the substrate, and an LED chip provided on the metal layer, wherein the metal layer includes a first region for heat dissipation and two second regions for electric conduction, and the first region and the two second regions are respectively electrically insulated from each other, and wherein the LED chip is provided in the first region and is electrically connected with the two second regions via wires. According to various embodiments, a metal layer for electric conduction and a metal layer for heat dissipation are provided, respectively, and these metal layers are electrically insulated from each other, so that there is no need to consider the insulation problem during configuration of the thermal conductive metal layer, thus the thermal dissipating performance of the LED lighting assembly can be improved by various means.

According to various embodiments, the substrate is a FR4 substrate. Compared with a ceramic printed circuit board substrate and a metal chip printed circuit board substrate, the cost of the FR4 substrate is lower, reducing the cost of the whole LED lighting assembly on the whole.

Preferably, at least one thermal via is provided. The thermal via penetrates the substrate in a portion of the first region where the LED chip is not provided. The heat from the metal layer cannot be dissipated quickly to the outside since the FR4 substrate has a poor thermal conducting performance, then the thermal dissipating performance of the LED lighting assembly will be greatly improved by providing the thermal via on the substrate and the metal layer, and the service life of the LED chip will be prolonged, and the luminescent efficiency will be improved.

Further preferably, the first region includes two first subregions and a second subregion between the two first subregions and connecting the two first subregions, the thermal via is provided in the first subregion, and the LED chip is provided in the second subregion. According to various embodiments, the second subregion is configured for arrangement of the LED chip, and is connected with the two first subregions, thus, the heat from the LED chip will be transferred to the first subregions through the second subregion. Preferably, the two first subregions are symmetrical to each other, thus, the heat will be transferred uniformly to the two first subregions. Besides, since the first subregion is provided with the thermal via, it is more favorable for thermal dissipation through the thermal via. According to various embodiments, the first region for the arrangement of the LED chip is insulated from the LED chip as the COB chip-on-board package technology is used. Therefore, the thermal via can be provided freely on the first region without undesired short circuit of the LED chip caused by the thermal via.

Particularly preferably, the second subregion has a size at least the same as that of the LED chip, and the two second regions are arranged on both sides of the second subregion not connected with the first subregions. In the COB chip-on-board package, the LED chip needs to be electrically connected, via a wire, with an electric conducting path, i.e., the second regions. Such configuration of the second regions according to various embodiments advantageously shortens a length of the wire, thus effectively reducing a thermal resistance and the cost as well.

According to various embodiments, the metal layer is a copper layer. Copper is a good conductor with excellent electric conducting and thermal conducting performances. Thus, using the copper layer as the metal layer for heat dissipation and electric conduction is favorable for reducing the resistance of the second regions as the electric conducting path and is more favorable for improvement of the thermal dissipating performance of the LED lighting assembly.

Further according to various embodiments, the wire is made from a gold wire, an aluminum wire or a copper wire. Since the gold wire has the advantages of a big electrical conductivity, wear-resistance, and good toughness, the gold wire is usually used as the wire in the COB chip-on-board package, while the aluminum wire or copper wire also may be used as the wire so as to reduce the cost.

According to various embodiments, the illuminating apparatus has a plurality of LED lighting assemblies of the above type, wherein respective LED lighting assemblies are electrically connected with each other through the second regions. The illuminating apparatus according to various embodiments has a low cost and a good thermal dissipating performance as well.

### BRIEF DESCRIPTION OF THE DRAWINGS

In the drawings, like reference characters generally refer to the same parts throughout the different views.

The drawings are not necessarily to scale, emphasis instead generally being placed upon illustrating the principles of the disclosed embodiments. In the following description, various embodiments described with reference to the following drawings, in which:

FIG. 1 is a schematic diagram of an LED lighting assembly according to the disclosure; and

FIG. 2 is a schematic diagram of an illuminating apparatus having a plurality of LED lighting assemblies according to the disclosure.

### DETAILED DESCRIPTION

The following detailed description refers to the accompanying drawing that show, by way of illustration, specific details and embodiments in which the disclosure may be practiced.

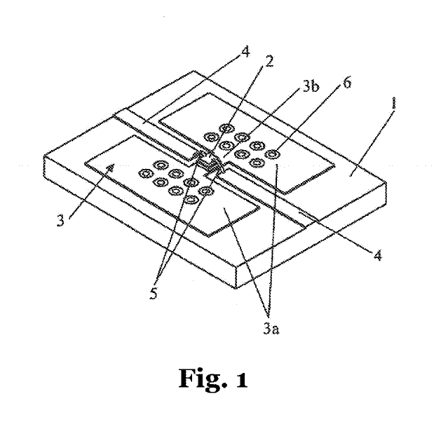

FIG. 1 is a schematic diagram of an LED lighting assembly according to the disclosure. It can be seen from the figure that the LED lighting assembly has an FR4 substrate 1, a metal layer made from copper and applied on the FR4 substrate 1, and an LED chip 2 provided on the metal layer. As can be seen from the figure, the metal layer is divided into two portions, i.e., a first region 3 for heat dissipation and two second regions 4 for electric conduction, and the first region 3 and the two second regions 4 are electrically insulated from each other so as to form on the FR4 substrate 1 independent electric conduction regions and independent heat dissipation region, respectively. As further can be seen from the figure, the first region 3 is divided into two first subregions 3a symmetrical to each other and a second subregion 3b between the two first subregions 3a and connecting the two first subregions 3a. In the present embodiment, the second subregion 3b is connected between the two first subregions 3a so as to form two notches on both sides of the second subregion 3b between the two first subregions 3a, and the two second regions 4 are just arranged in respective notches, thus the two second regions 4 are arranged on both sides of the second subregion 3b not connected with the first subregions 3a, so that the first region 3 form into a dumbbell shape

In the present embodiment, the LED chip 2 is provided in the second subregion 3b that has a size just capable of bearing the LED chip 2, and the LED chip 2 is electrically connected with respective second regions 4 via a wire 5 configured as a gold wire. At the same time, the two first subregions 3a are further provided with thermal vias 6, respectively. The thermal vias 6 extend and penetrate the FR4 substrate 1 so as to provide a good thermal dissipating performance for the LED lighting assembly.

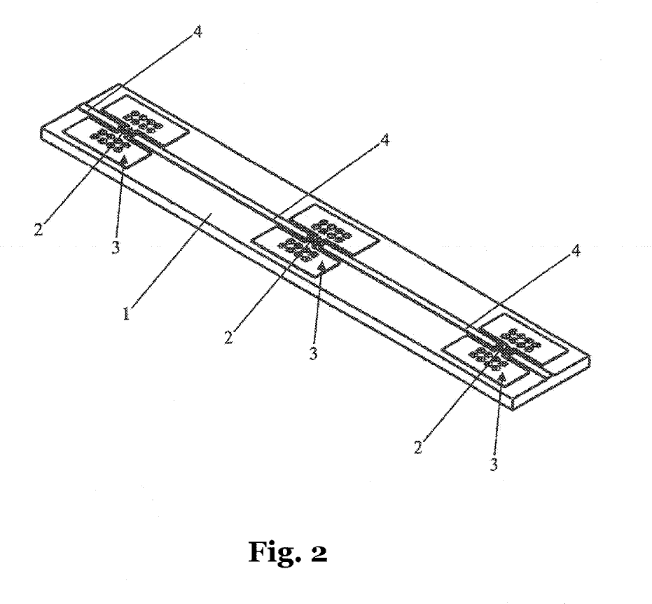

FIG. 2 is a schematic diagram of an illuminating apparatus having a plurality of LED lighting assemblies according to the disclosure. As can be seen from the figure, a plurality of LED lighting assemblies are connected in series in the illuminating apparatus. These LED lighting assemblies are connected in series with each other through the second regions 4.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

### LIST OF REFERENCE SIGNS

1 FR4 substrate
2 LED chip
3 first region
3a first subregion
3b second subregion
4 second region
5 wire
6 thermal via

1. An LED lighting assembly, comprising:
a substrate,
a metal layer applied on the substrate, and
an LED chip provided on the metal layer, wherein the metal layer comprises a first region for heat dissipation and two second regions for electric conduction, and the first region and the two second regions are electrically insulated from each other, and wherein the LED chip is provided in the first region and is respectively electrically connected with the two second regions via wires.

2. The LED lighting assembly according to claim 1, wherein the substrate is a FR4 substrate.

3. The LED lighting assembly according to claim 1, wherein at least one thermal via is provided, and the thermal via penetrates the substrate in a portion of the first region where the LED chip is not provided.

4. The LED lighting assembly according to claim 3, wherein the first region comprises two first subregions and a second subregion connecting the two first subregions therebetween, the thermal via is provided in the first subregion, and the LED chip is provided in the second subregion.

5. The LED lighting assembly according to claim 4, wherein the two first subregions are symmetrical to each other.

6. The LED lighting assembly according to claim 4, wherein the second subregion has a size at least the same as that of the LED chip.

7. The LED lighting assembly according to claim 4, wherein the two second regions are arranged on two sides, which are not connected with the first subregions, of the second subregion.

8. The LED lighting assembly according to claim 1, wherein the metal layer is a copper layer.

9. The LED lighting assembly according to claim 1, wherein the wire is made from a gold wire, an aluminum wire or a copper wire.

10. An illuminating apparatus, wherein the illuminating apparatus has a plurality of LED light assemblies
the LED lighting assembly, comprising:
a substrate,
a metal layer applied on the substrate, and
an LED chip provided on the metal layer, wherein the metal layer comprises a first region for heat dissipation and two second regions for electric conduction, and the first region and the two second regions are electrically insulated from each other, and wherein the LED chip is provided in the first region and is respectively electrically the two second regions via wires,
and wherein the LED lighting assemblies are electrically connected with each other through the second regions.
